(19) United States
(12) Patent Application Publication
(10) Pub. No.: US 2018/0315714 A1
(43) Pub. Date: Nov. 1, 2018

(54) CHIP PACKAGE STRUCTURE AND MANUFACTURING METHOD THEREOF

(71) Applicant: Unimicron Technology Corp., Taoyuan City (TW)

(72) Inventors: Jui-Chun Kuo, New Taipei City (TW); Chuang-Yi Chiu, Taoyuan City (TW); Kuei-Sheng Wu, Taoyuan City (TW); Wen-Shen Lo, New Taipei City (TW)

(73) Assignee: Unimicron Technology Corp., Taoyuan City (TW)

(21) Appl. No.: 15/498,435

(22) Filed: Apr. 26, 2017

(51) Int. Cl. H01L 23/552; H01L 23/66; H01L 23/055; H01L 23/31; H01L 23/06; H01L 21/52; H01L 21/48; H01L 21/56

(52) U.S. Cl. CPC H01L 23/552; H01L 23/66; H01L 23/055; H01L 23/3128; H01L 24/49; H01L 21/52; H01L 21/4846; H01L 21/565; H01L 2223/6677; H01L 23/06

(57) ABSTRACT

A chip package structure and a manufacturing method thereof are provided. The chip package structure includes a circuit board, a chip, a housing, an antenna pattern, a conductive line pattern and a shielding layer. The chip is disposed on the circuit board. The housing is disposed on the circuit board and covers the chip, wherein the housing includes a cover and sidewalls, and the housing contains catalyst particles. The antenna pattern is disposed on an outer surface of the cover. The conductive line pattern is disposed on an outer surface of the sidewalls and electrically connected to the antenna pattern and the circuit board. The shielding layer is disposed at least on an inner surface of the cover.

### BACKGROUND OF THE INVENTION

### Field of the Invention

The invention relates to a chip package structure, and particularly relates to a chip package structure having a housing including an antenna pattern and a shielding layer.

### Description of Related Art

For a present chip package structure having an antenna layer, in a manufacturing process, the antenna layer and a chip are usually disposed on a circuit board simultaneously, and then the antenna layer and the chip are covered using a molding compound.

However, in the aforementioned chip package structure, since the antenna layer and the chip are disposed on the circuit board simultaneously, a larger area of the circuit board is required to meet the structural design requirements. Therefore, the product having the chip package structure will have a larger size, and it is not easy to meet the requirements of miniaturization and lightweight of electronic products currently.

### SUMMARY OF THE INVENTION

The invention provides a chip package structure having a housing including an antenna pattern and a shielding layer.

The invention provides a manufacturing method of a chip package structure that a housing including an antenna pattern and a shielding layer is covered on a chip.

The invention provides a chip package structure including a circuit board, a chip, a housing, an antenna pattern, a conductive line pattern and a shielding layer. The chip is disposed on the circuit board. The housing is disposed on the circuit board and covers the chip. The housing includes a cover and sidewalls, and the housing contains catalyst particles. The antenna pattern is disposed on an outer surface of the cover. The conductive line pattern is disposed on an outer surface of the sidewalls and electrically connected to the antenna pattern and the circuit board. The shielding layer is disposed at least on an inner surface of the cover.

According to an embodiment of the invention, the shielding layer is disposed in the whole inner surface of the housing, for example.

According to an embodiment of the invention, a thickness of the shielding layer is not more than 30 μm, for example.

According to an embodiment of the invention, the chip package structure further includes a molding compound. The molding compound covers the chip.

According to an embodiment of the invention, the catalyst particles are metal particles, graphite particles, or a combination thereof, for example.

The invention provides a manufacturing method of a chip package structure including the following steps. A housing is formed. The housing includes a cover and sidewalls, and the housing contains catalyst particles. An antenna pattern trench is formed on an outer surface of the cover. A conductive line pattern trench is formed on an outer surface of the sidewalls. A shielding pattern trench is formed at least on an inner surface of the cover. The catalyst particles are exposed simultaneously. A conductive layer is formed in the antenna pattern trench, the conductive line pattern trench and the shielding pattern trench. The antenna pattern trench is formed with an antenna pattern. The conductive line pattern trench is formed with a conductive line pattern. The shielding pattern trench is formed with a shielding layer. A chip is disposed on a circuit board. The housing is disposed on the circuit board and covers the chip, and the conductive line pattern is electrically connected to the antenna pattern and the circuit board.

According to an embodiment of the invention, a method of forming the housing is to perform an injection molding process, for example.

According to an embodiment of the invention, a method of forming the antenna pattern trench, the conductive line pattern trench and the shielding pattern trench is to perform a laser engraving process, for example.

According to an embodiment of the invention, a method of forming the conductive layer is to perform a chemical deposition process or an electroless plating process, for example.

According to an embodiment of the invention, a method of disposing the housing on the circuit board is to perform a surface mounting technology (SMT) process, for example.

According to an embodiment of the invention, the shielding pattern trench is formed in the whole inner surface of the housing, for example.

According to an embodiment of the invention, a thickness of the shielding layer is not more than 30 μm, for example.

According to an embodiment of the invention, after the chip is disposed on the circuit board and before the housing is disposed on the circuit board, the manufacturing method of the chip package structure further includes forming a molding compound covering the chip.

Based on the above, in the invention, the housing is formed using the material containing the catalyst particles, and the catalyst particles are used as a seed layer to form the antenna pattern and the shielding layer in the housing. Thus, process steps can be simplified, and the formed antenna pattern and the shielding layer can have a thinner thickness. Additionally, in the invention, both the antenna pattern and the shielding layer are disposed above the chip. Thus, it is not necessary to occupy additional regions of the circuit board, so that the formed chip package structure can meet the requirements of miniaturization.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are schematic cross-sectional views of a process flow of a chip package structure according to an embodiment of the invention.

FIG. 2A and FIG. 2B are schematic three-dimensional views of a housing according to an embodiment of the invention.

FIG. 3 is a schematic cross-sectional view of the housing according to another embodiment of the invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In the following embodiments, after an antenna pattern and a shielding layer are formed on a housing, the housing is bonded to a circuit board which a chip is disposed thereon. The manufacturing process of the housing and the process of disposing the chip on the circuit board may be performed separately, and the invention does not limit the order of the two.

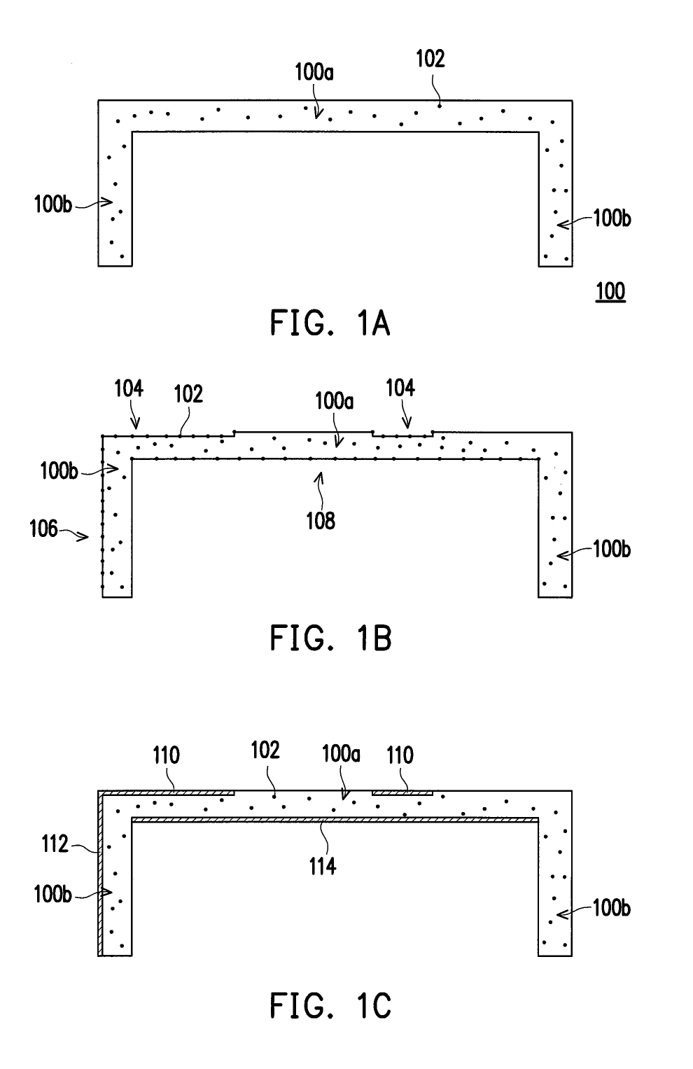

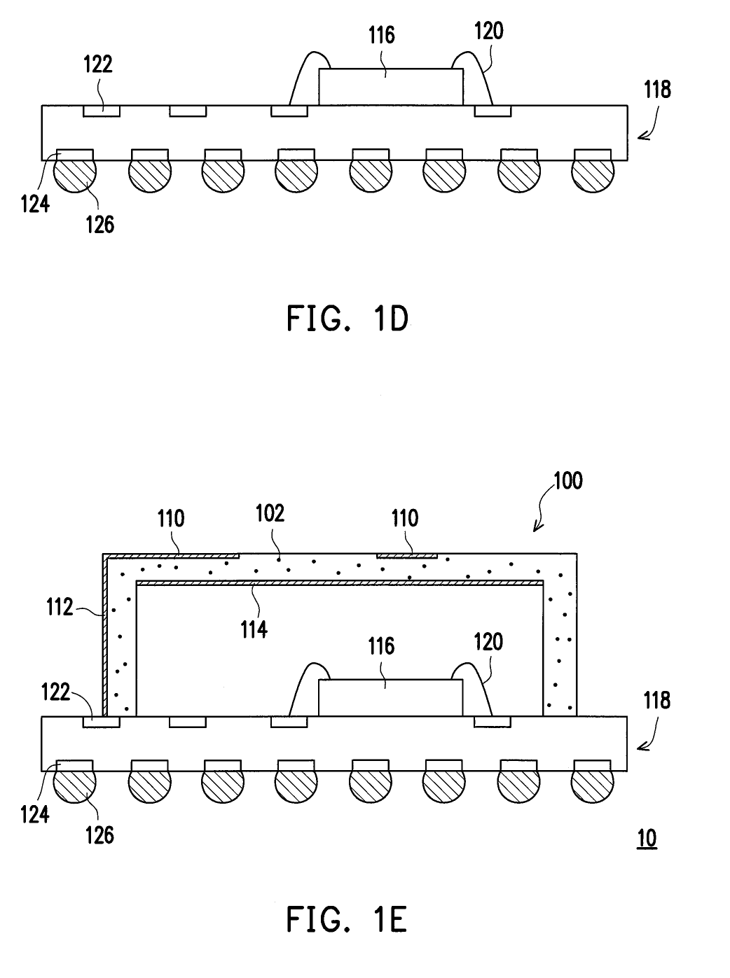

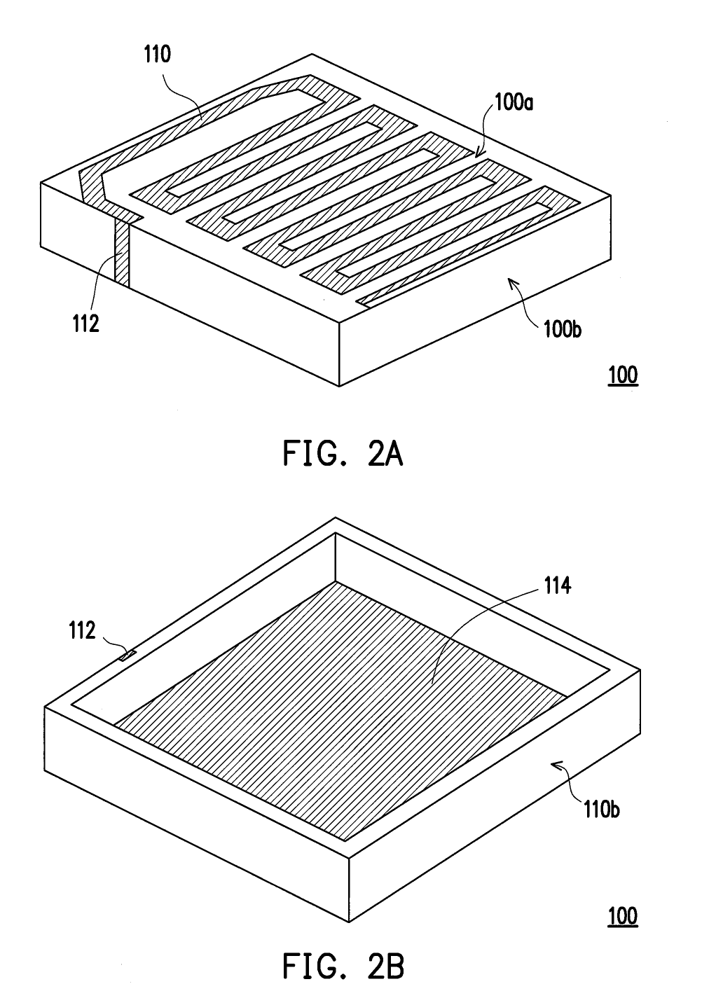

FIG. 1A to FIG. 1E are schematic cross-sectional views of a process flow of a chip package structure according to an embodiment of the invention. First, referring to FIG. 1A, a housing 100 is formed. The housing 100 is used to cover the chip disposed on the circuit board. A material of the housing 100 is an insulating material, such as plastic. Additionally, the housing 100 contains catalyst particles 102. The catalyst particles 102 are metal particles, graphite particles, or a combination thereof, for example. A method of forming the housing 100 is to perform an injection molding process using an insulating material mixed with the catalyst particles 102, for example. Thus, the catalyst particles 102 may be uniformly dispersed in the housing 100. The housing 100 includes a cover 100a and sidewalls 100b. In the embodiment, the housing 100 is a rectangular housing (as shown in FIG. 2A and FIG. 2B), and therefore has four sidewalls 100b connecting to the cover 100a, but the invention is not limited thereto. In other embodiments, depending on the actual needs, the housing 100 may also be a housing having other shapes.

Then, referring to FIG. 1B, an antenna pattern trench 104 is formed in an outer surface of the cover 100a, a conductive line pattern trench 106 is formed in an outer surface of the sidewalls 100b, and a shielding pattern trench 108 is formed in an inner surface of the cover 100a. The conductive line pattern trench 106 is connected to the antenna pattern trench 104. In this article, the “inner surface” represents a surface adjacent to a space covered by the housing 100, and the “outer surface” represents a surface opposite to the “inner surface” of the housing 100. A method of forming the antenna pattern trench 104, the conductive line pattern trench 106 and the shielding pattern trench 108 is to perform a laser engraving process on the housing 100, for example. In the process of engraving the housing 100 with laser, a portion of the housing 100 may be removed by the laser. At this time, in the engraved region, the catalyst particles 102 contained in the housing 100 will be exposed and absorb the energy of the laser to be “activated”. As shown in FIG. 1B, the catalyst particles 102 are exposed at the sidewalls and the bottoms of the antenna pattern trench 104, the conductive line pattern trench 106 and the shielding pattern trench 108.

The antenna pattern trench 104, the conductive line pattern trench 106 and the shielding pattern trench 108 are the regions where an antenna pattern, a conductive line pattern and a shielding layer are subsequently formed, and the exposed catalyst particles 102 may be used as a seed layer for forming the antenna pattern, the conductive line pattern and the shielding layer. Thus, according to the required thickness of the antenna pattern, the conductive line pattern and the shielding layer, the depth of the trench formed by the laser engraving can be controlled. In the embodiment, the depth of the antenna pattern trench 104, the conductive line pattern trench 106 and the shielding pattern trench 108 is not more than 30 μm. That is, the thickness of the antenna pattern, the conductive line pattern and the shielding layer subsequently formed in the antenna pattern trench 104, the conductive line pattern trench 106 and the shielding pattern trench 108 is not more than 30 μm. In this thickness range, the antenna pattern, the conductive line pattern and the shielding layer may have the required electrical properties, and it will not waste too much material because of the thickness which is too thick.

Then, referring to FIG. 1C, a conductive layer is formed in the antenna pattern trench 104, the conductive line pattern trench 106 and the shielding pattern trench 108. A method of forming the conductive layer is to perform a chemical deposition process or an electroless plating process using the activated catalyst particles 102 (exposed in the trench) as the seed layer, for example. The conductive layer formed in the antenna pattern trench 104 is used as an antenna pattern 110. The conductive layer formed in the conductive line pattern trench 106 is used as a conductive line pattern 112. The conductive layer formed in the shielding pattern trench 108 is used as a shielding layer 114. The conductive line pattern 112 is connected to the antenna pattern 110. Thus, the antenna pattern 110 may be electrically connected to other components by the conductive line pattern 112. The shielding layer 114 is used to prevent the components covered by the housing 100 from being affected by electromagnetic effects from the antenna pattern 110 and other outside electromagnetic waves, so as to prevent the electronic signal from being disturbed which results in signal loss.

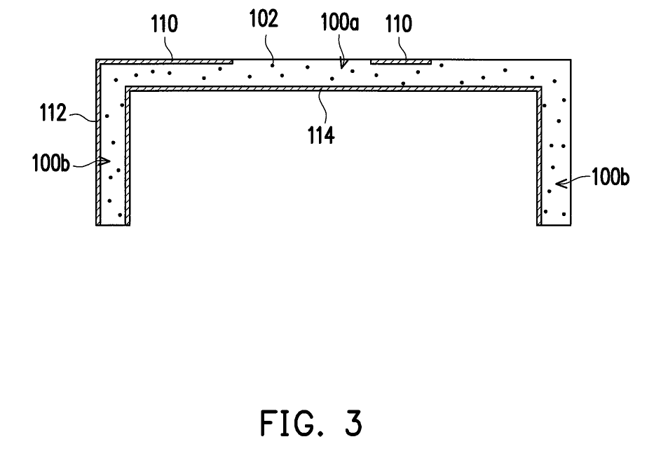

In the embodiment, the shape of the antenna pattern 110 is not limited by FIG. 2A. In other embodiments, the antenna pattern 110 may be formed in any shape depending on the actual needs. Additionally, in the embodiment, the conductive line pattern 112 is only formed in one sidewall 100b, but the invention is not limited thereto. In other embodiments, the conductive line pattern 112 may be formed in a plurality of sidewalls 100b to be connected to the antenna pattern 110. Additionally, in the embodiment, the shielding layer 114 is only formed in an inner surface of the cover 100a, but the invention is not limited thereto. In other embodiments, the shielding layer 114 may also be formed on the whole inner surface of the housing 100. That is, the shielding layer 114 is formed on the inner surface of the cover 100a and on the inner surface of all the sidewalls 100b, so that the electromagnetic shielding effect of the shielding layer 114 is further improved as shown in FIG. 3.

Referring to FIG. 1D, a chip 116 is disposed on a circuit board 118. In the embodiment, the chip 116 is connected to a pad 122 of the circuit board 118 via a wire 120 by a wire bonding method, so that the chip 116 is electrically connected to the circuit board 118. In other embodiments, the chip 116 may also be electrically connected to the circuit board 118 by a flip chip method. Additionally, solder balls 126 are formed on the pad 124 at the bottom of the circuit board 118. The solder balls 126 are used as contact points for connecting the circuit board 118 to outside components.

Thereafter, referring to FIG. 1E, the housing 100 is disposed on the circuit board 118, and the housing 100 covers the chip 116, so as to complete a chip package structure 10 of the embodiment. A method of disposing the housing 100 on the circuit board 118 is to perform a surface mounting technology process, for example. After the housing 100 is disposed on the circuit board 118, the conductive line pattern 112 may be connected to the pad 122 of the circuit board 118, so that the antenna pattern 110 is electrically connected to the circuit board 118. In the chip package structure 10, since the shielding layer 114 is located between the antenna pattern 110 and the chip 116, it can prevent the chip 116 from being affected by the electromagnetic effects from the antenna pattern 110 and other outside electromagnetic waves, so as to prevent the electronic signal from being disturbed which results in the signal loss.

In the embodiment, after the chip 116 is disposed on the circuit board 118, the housing 100 may be directly disposed on the circuit board 118, without the need to form a molding compound to cover the chip 118 in advance. In other embodiments, it is also possible to form the molding compound covering the chip 116 on the circuit board 118 after the chip 116 is disposed on the circuit board 118. Then, the housing 100 is disposed on the circuit board 118.

Additionally, in the embodiment, both the antenna pattern 110 and the shielding layer 114 are located above the chip 116. Thus, it is not necessary to use other regions of the circuit board 118 to set the antenna pattern and the shielding layer. Therefore, the chip package structure 10 may have a smaller size to meet the requirements of miniaturization.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A chip package structure, comprising:
a circuit board;
a chip, disposed on the circuit board;
a housing, disposed on the circuit board and covering the chip, wherein the housing comprises a cover and sidewalls, and the housing contains catalyst particles;
an antenna pattern, disposed on an outer surface of the cover;
a conductive line pattern, disposed on an outer surface of the sidewalls and electrically connected to the antenna pattern and the circuit board; and
a shielding layer, disposed at least on an inner surface of the cover, wherein a thickness of the shielding layer is not more than 30 μm.

2. The chip package structure according to claim 1, wherein the shielding layer is disposed on the whole inner surface of the housing.

3. (canceled)

4. The chip package structure according to claim 1, further comprising a molding compound, the molding compound covering the chip.

5. The chip package structure according to claim 1, wherein the catalyst particles comprise metal particles, graphite particles, or a combination thereof.

6. A manufacturing method of a chip package structure, comprising:
forming a housing, the housing comprising a cover and sidewalls, and the housing containing catalyst particles;
forming an antenna pattern trench on an outer surface of the cover, forming a conductive line pattern trench on an outer surface of the sidewalls and forming a shielding pattern trench at least on an inner surface of the cover, and exposing the catalyst particles simultaneously;
forming a conductive layer in the antenna pattern trench, the conductive line pattern trench and the shielding pattern trench, wherein the antenna pattern trench is formed with an antenna pattern, the conductive line pattern trench is formed with a conductive line pattern, and the shielding pattern trench is formed with a shielding layer;
disposing a chip on a circuit board; and
disposing the housing on the circuit board and covering the chip, and the conductive line pattern being electrically connected to the antenna pattern and the circuit board.

7. The manufacturing method of the chip package structure according to claim 6, wherein a method of forming the housing comprises performing an injection molding process.

8. The manufacturing method of the chip package structure according to claim 6, wherein a method of forming the antenna pattern trench, the conductive line pattern trench and the shielding pattern trench comprises performing a laser engraving process.

9. The manufacturing method of the chip package structure according to claim 6, wherein a method of forming the conductive layer comprises performing a chemical deposition process or an electroless plating process.

10. The manufacturing method of the chip package structure according to claim 6, wherein a method of disposing the housing on the circuit board comprises performing a surface mounting technology process.

11. The manufacturing method of the chip package structure according to claim 6, wherein the shielding pattern trench is formed on the whole inner surface of the housing.

12. The manufacturing method of the chip package structure according to claim 6, wherein a thickness of the shielding layer is not more than 30 nm.

13. The manufacturing method of the chip package structure according to claim 6, wherein after disposing the chip on the circuit board and before disposing the housing on the circuit board, further comprising forming a molding compound covering the chip.
